(19) United States
(12) Patent Application Publication
(10) Pub. No.: US 2026/0279057 A1
(43) Pub. Date: Sep. 17, 2026

(54) MOUNTING ASSISTANCE DEVICE

(71) Applicant: FUJI CORPORATION, Chiryu (JP)

(72) Inventors: Mikiya SUZUKI, Nishio-shi (JP); Takahiro KOBAYASHI, Chiryu-shi (JP); Yuta YOKOI, Kariya-shi (JP); Kenshiro NISHIDA, Handa-shi (JP); Tomotaka TAKEUCHI, Ama-shi (JP)

(73) Assignee: FUJI CORPORATION, Chiryu (JP)

(21) Appl. No.: 19/471,200

(22) PCT Filed: Apr. 4, 2023
(86) PCT No.: PCT/JP2023/013957

§ 371 Date: Sep. 30, 2025

(51) Int. Cl. G06V 20/50; G06V 10/25; G06V 10/44

(52) U.S. Cl. CPC G06V 20/50; G06V 10/25; G06V 10/44; G06V 2201/06

(57) ABSTRACT

A mounting assistance device includes a recognition section configured to perform image processing on image data acquired by capturing an image of a supply region in which multiple components are supplied in a bulk state, and recognize the component in the supply region, the image processing including a generation step of generating multiple blobs, an extraction step of extracting a candidate blob corresponding to a closed region of at least a part of the component from among the multiple blobs, and a recognition step of recognizing a rectangular region including one or more of the candidate blobs as the component in the image data, and a determination section configured to determine whether the component is appropriate for a target of a collection operation by a component mounter based on a shape or an area of the recognized component.

### TECHNICAL FIELD

The present disclosure relates to a mounting assistance device.

### BACKGROUND ART

A mounting assistance device assists a mounting process by a component mounter using a bulk feeder. The bulk feeder is equipped in a component mounter that mounts a component on a board, and supplies components in a bulk state (refer to Patent Literature 1). In a mounting process, a component mounter performs image processing for recognizing a supply state of a component by such a bulk feeder, and controls an operation of picking up components by using a suction nozzle based on a result of the image processing.

### CITATION LIST

### Patent Literature

Patent Literature 1: JP2011-114084

### BRIEF SUMMARY

### Technical Problem

Image processing for recognizing a supply state includes a determination of whether a component supplied to a supply region of a bulk feeder is appropriate for a target of a collection operation by a component mounter. When there is an erroneous determination in such image processing, the erroneous determination may cause a mistake in the collection operation, and even when collection can be performed, processing to be performed thereafter may be affected.

An object of the present description is to provide a mounting assistance device that assists a mounting process by improving accuracy of image processing for recognizing a supply state of a component by a bulk feeder.

### Solution to Problem

The present description discloses a mounting assistance device including a recognition section configured to perform image processing on image data acquired by capturing an image of a supply region in which multiple components are supplied in a bulk state, and recognize the component in the supply region, the image processing including a generation step of generating multiple blobs, an extraction step of extracting a candidate blob corresponding to a closed region of at least a part of the component from among the multiple blobs, and a recognition step of recognizing a rectangular region including one or more of the candidate blobs as the component in the image data, and a determination section configured to determine whether the component is appropriate for a target of a collection operation by a component mounter based on a shape or an area of the recognized component.

The present description includes a mounting assistance device including a recognition section configured to perform image processing on image data acquired by capturing an image of a supply region in which multiple cavities individually accommodating multiple components are formed and recognize a position and a shape of the component in the supply region, and a determination section configured to determine whether the component is appropriate for a target of a collection operation by a component mounter based on whether entirety of the recognized component is accommodated in the cavity closest to the component in the image data.

### Advantageous Effects

With a configuration of the first mounting assistance device, it is determined whether a recognized component is appropriate for a target of a collection operation based on a shape or an area of the recognized component by using a blob. In addition, with a configuration of the second mounting assistance device, it is determined whether a recognized component is appropriate for a target of a collection operation based on whether entirety of the recognized component is accommodated in a cavity. With such a configuration, accuracy of image processing can be improved. Accordingly, it is possible to prevent a mistake from occurring in a collection operation by a component mounter, and as a result, it is possible to maintain high productivity in the component mounter.

### BRIEF DESCRIPTION OF DRAWINGS

FIG. 1 is a plan view schematically illustrating a component mounter.

FIG. 2 is a side view schematically illustrating a part of a bulk feeder including a supply region.

FIG. 3 is a plan view as viewed from a III direction of FIG. 2.

FIG. 4 is a block diagram illustrating a component mounter to which a mounting assistance device is applied.

FIG. 5 is a flowchart illustrating recognition processing of a supply state.

FIG. 6 is a view illustrating image data obtained by capturing an image of the supply region.

FIG. 7 is an enlarged view illustrating image data obtained by performing blob generation processing.

FIG. 8 is an enlarged view illustrating a part extracted from FIG. 7.

FIG. 9 is a view illustrating a virtual component recognized as a blob in image data.

FIG. 10 is a view illustrating a relationship between the center of a recognized component and a region where a component center can be located in a cavity.

FIG. 11 is a view illustrating a component accommodated in a cavity in a normal posture, two components accommodated in a cavity in an abnormal posture, and a blob corresponding thereto.

FIG. 12 is a view illustrating a relationship between a supply angle of a recognized component and a defined angle in a cavity.

FIG. 13 is a view illustrating multiple components inappropriate for collection in the supply region and a blob corresponding thereto.

### DESCRIPTION OF EMBODIMENTS

### 1. Outline of Mounting Assistance Device 50

Mounting assistance device 50 assists a mounting process by component mounter 10 using bulk feeder 30. In the present embodiment, mounting assistance device 50 is incorporated in control device 20 of component mounter 10. Mounting assistance device 50 improves accuracy of image processing for recognizing a supply state of a component supplied by bulk feeder 30, thereby suppressing occurrence of a mistake in a collection operation in a mounting process.

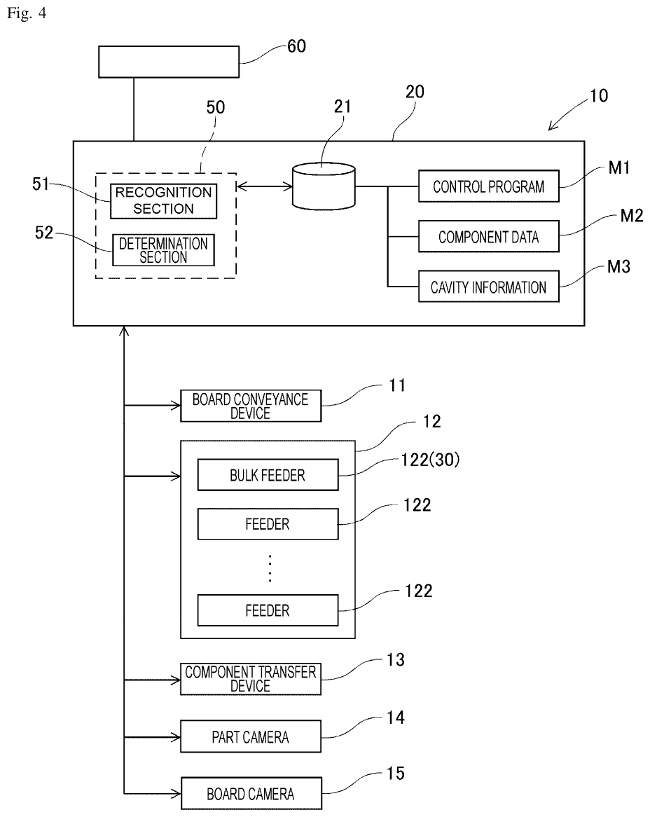

Above-described component mounter 10 performs a mounting process of mounting a component on board 91 as a predetermined board work. Component mounter 10 configures a production line installed in a conveyance direction of board 91 together with another board work machine. Each of multiple board work machines is communicably connected to host computer 60 (see FIG. 4) that collectively controls the production line. The production line includes a printer, component mounter 10, a reflow oven, and an inspector as multiple board work machines.

### 2. Configuration of Component Mounter 10

### 2-1. Board Conveyance Device 11

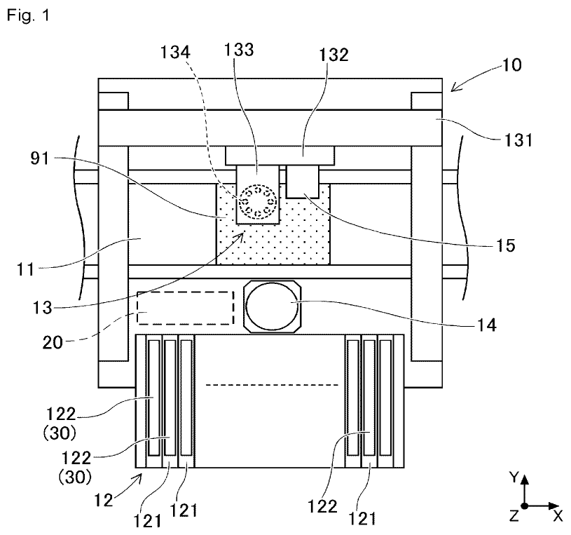

As illustrated in FIG. 1, component mounter 10 includes board conveyance device 11. Board conveyance device 11 subsequently conveys board 91 in a conveyance direction and positions board 91 at a predetermined position within the mounter.

### 2-2. Component Supply Device 12

Component mounter 10 includes component supply device 12. Component supply device 12 supplies a component to be mounted on board 91. In component supply device 12, feeder 122 is set in each of multiple slots 121. A tape feeder that supplies a component to be collectable, for example, by feeding and moving a carrier tape accommodating a large number of components is applied to feeder 122. In addition, bulk feeder 30 which supplies a component accommodated in a bulk state to be collectable is applied to feeder 122. Details of bulk feeder 30 will be described below.

### 2-3. Component Transfer Device 13

Component mounter 10 includes component transfer device 13. Component transfer device 13 transfers a component supplied by component supply device 12 in a predetermined mounting position on board 91. Component transfer device 13 includes head driving device 131, movement table 132, mounting head 133, and suction nozzle 134. Head driving device 131 moves movement table 132 in a horizontal direction (X direction and Y direction) by a linear movement mechanism. Mounting head 133 is detachably fixed to movement table 132 by a clamp member (not illustrated) and is provided movably in the horizontal direction within the mounter.

Mounting head 133 rotatably, liftably, and lowerably supports multiple suction nozzles 134. Suction nozzle 134 is a holding member that collects and holds a component supplied by feeder 122. Suction nozzle 134 picks up a component supplied by feeder 122 by using supplied negative pressure air. A chuck or the like that holds a component by gripping the component can be adopted as a holding member to be attached to mounting head 133.

### 2-4. Part Camera 14 and Board Camera 15

Component mounter 10 includes part camera 14 and board camera 15. Part camera 14 and board camera 15 are digital imaging devices having imaging elements, such as CMOS. Part camera 14 and board camera 15 capture an image based on a control signal and send image data acquired by the image capturing. Part camera 14 is configured to be able to capture an image of a component held by suction nozzle 134 from below. Board camera 15 is provided movably on movement table 132 in the horizontal direction and integrally with mounting head 133. Board camera 15 is configured to be able to capture an image of board 91 from above.

In addition, board camera 15 can use various devices or the like as an imaging target as long as the various devices are within an operation range of movement table 132 in addition to using a surface of board 91 as an imaging target. For example, in the present embodiment, as illustrated in FIG. 3, board camera 15 can capture an image of supply region As to which bulk feeder 30 supplies a component or reference mark 49 provided on an upper part of bulk feeder 30 within a camera field of view. As described above, board camera 15 can be used commonly to capture images of different imaging targets to acquire image data used for various pieces of image processing.

### 2-5. Control Device 20

As illustrated in FIG. 1, component mounter 10 includes control device 20. Control device 20 is mainly configured with CPU, various types of memories, and a control circuit. Control device 20 includes storage section 21 as illustrated in FIG. 4. Storage section 21 is configured with a hard disk device or a storage device such as a flash memory. Storage section 21 of control device 20 stores various data such as control program M1, component data M2, and cavity information M3, which are used for controlling a mounting process.

Control program M1 illustrates in a scheduled mounting order a mounting position, a mounting angle, and a component type of the component to be mounted on board 91 in a mounting process. Here, the mounting process includes a process of repeating multiple times a pick-and-place cycle (PP cycle) which includes a collection cycle and a mounting cycle. The above-described “collection cycle” is a process of repeating a collection operation by suction nozzle 134 to collect the components supplied by component supply device 12, multiple times.

In addition, the above-described “mounting cycle” is a process of repeating multiple times a mounting operation of mounting a collected component at a predetermined mounting position of board 91 and at a predetermined mounting angle. As described above, a performance order of the PP cycle configured with multiple collection operations and mounting operations grouped in consideration of the number of suction nozzles 134 supported by mounting head 133, a movement distance of mounting head 133, and the like is set in advance in control program M1.

Component data M2 includes shape data for each type of component. The above-described “shape data” includes at least one of an outer edge shape of a component, a shape of a characteristic portion of the component, and a dimension of the component. The “outer edge shape” of the component corresponds to a shape of the outer edge when the inside of the component and a background thereof are divided by using an outer edge of the component as a boundary.

The “shape of the characteristic portion” of the component corresponds to a boundary shape of the characteristic portion in appearance due to a shape, a pattern, a color, and the like of the component. A corner portion, a bump, a terminal, a lead portion, or the like of the component can be applied as a characteristic portion of a component. In addition, component data M2 can include, for example, a maximum allowable movement speed (acceleration), a collection position (for example, a position in contact with suction nozzle 134), and the like for each component, in addition to the shape data.

Cavity information M3 is formed in supply region As of bulk feeder 30, and information on cavities 45 that individually accommodate components is associated with identification information (ID) of bulk feeder 30. Cavity information M3 can include a shape (including a length and depth of each side), a position, an orientation, the type of corresponding component, and the like of cavity 45 in supply region As. Details of processing to which cavity information M3 is applied will be described below.

Control device 20 performs recognition processing of a holding state of a component held by each of multiple holding members (suction nozzles 134). Specifically, control device 20 performs image processing on the image data acquired by capturing an image with part camera 14 and recognizes a position and an angle of each component with respect to a reference position of mounting head 133. In addition to part camera 14, for example, control device 20 may perform image processing on the image data acquired by capturing an image of a component from a side, below, or above by using a head camera unit or the like integrally provided on the mounting head 133.

In a mounting process, control device 20 controls a mounting operation by using mounting head 133 such that a component is mounted on board 91 in a predetermined posture. At this time, control device 20 controls the mounting operation based on a holding state of the recognized component. That is, control device 20 corrects a position of mounting head 133 and an angle of suction nozzle 134 around a Q axis to correct deviations of a position and an angle of a component held by suction nozzle 134 with respect to the Q axis (a rotation axis of suction nozzle 134). As a result, the component held by suction nozzle 134 is mounted at a predetermined mounting position and a predetermined mounting angle which are instructed by control program M1.

### 3. Configuration of Bulk Feeder 30

Bulk feeder 30 is set in component mounter 10 and functions as a part of component supply device 12. Bulk feeder 30 supplies a component accommodated in a component case in a bulk state (a dispersed state in which each posture is irregular) which is not packaged like a carrier tape. Accordingly, since bulk feeder 30 does not use a carrier tape unlike a tape feeder, there is an advantage in that loading of the carrier tape, collection of the used tape, and the like can be omitted.

For example, there is bulk feeder 30 of a type that supplies a component in an irregular posture to supply region As having a plane shape. However, when components are so close to be in contact with each other or accumulated (a state of being overlapped in a vertical direction) or the components are placed horizontally with width directions aligned in the vertical direction in supply region As, component mounter 10 cannot regard the components as collection targets. Therefore, in order to increase a ratio of collectable components, there is bulk feeder 30 of a type that supplies components to supply region As in an aligned state. In the present embodiment, bulk feeder 30 of a type in which components are aligned will be described as an example.

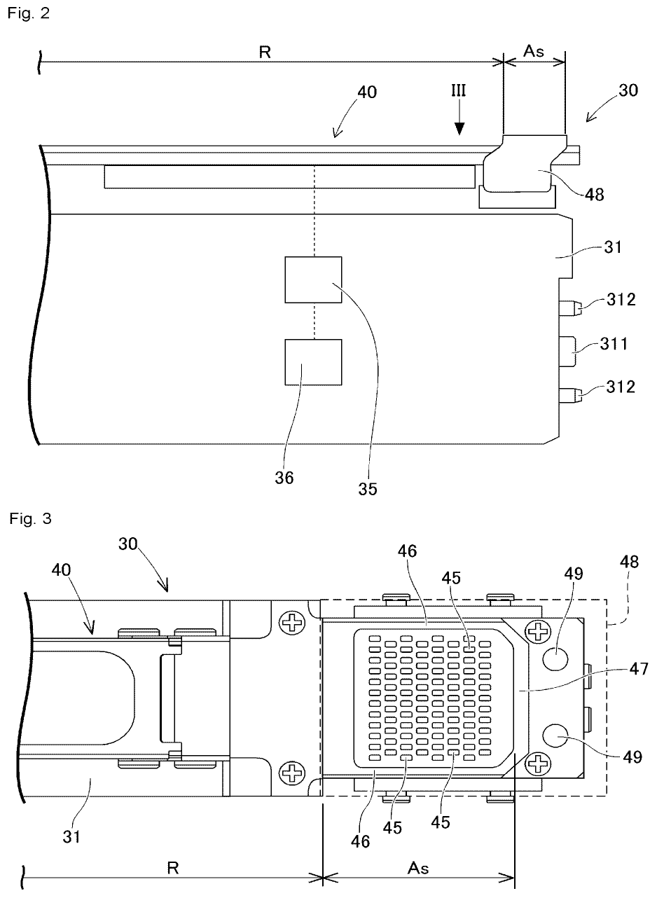

Bulk feeder 30 is provided with track unit 40 that is vibratably and detachably attached to feeder main body 31 formed in a flat box shape. Connector 311 and two positioning pins 312 are provided on a front portion (a right side end portion in FIG. 2) of feeder main body 31. When feeder main body 31 is set in slot 121 of component supply device 12, power is supplied via connector 311, and feeder main body 31 is communicable with control device 20 of component mounter 10.

Track unit 40 is vibrated by vibration application device 35. Track unit 40 is formed with conveyance path R through which multiple components are conveyed, and supply region As that communicates with conveyance path R and is open upward such that the multiple components are collectable. Track unit 40 is formed to extend in a front-rear direction (left-right direction in FIG. 3) of feeder main body 31. Pair of side walls 46, which protrudes upwards, is formed along both edges of track unit 40 in a width direction (a vertical direction in FIG. 3). Pair of side walls 46 is wall members that surround a peripheral edge of conveyance path R together with front end portion 47 of track unit 40 and prevent a component conveyed along conveyance path R from leaking out.

As illustrated in FIG. 3, multiple cavities 45 are formed in supply region As of track unit 40. Each of multiple cavities 45 is open upwards to accommodate a component in a posture in which a thickness direction of the component is in a vertical direction. In the present embodiment, multiple cavities 45 are disposed in a staggered shape. Here, “supply region As” of track unit 40 is a region to which a component is supplied in a bulk state, and is a region from which a component is collectable by suction nozzle 134 supported by mounting head 133. In addition, “conveyance path R” of track unit 40 is a passage of a component through which the component being distributed from a component case side to track unit 40 is conveyed to supply region As.

In addition, vibration application device 35 applies vibration to track unit 40 such that multiple components are conveyed along conveyance path R. When track unit 40 vibrates, forward and upward external force or a rearward and upward external force is applied to a component. As a result, multiple components are conveyed to a front side or a rear side of track unit 40. Bulk feeder 30 conveys a component as an operation of vibration application device 35 is controlled by feeder control device 36, and performs a supply operation of the component to supply region As. When components are accommodated in multiple cavities 45 by the supply operation, suction nozzle 134 is in a state of being able to collect the components.

Shutter 48 capable of closing and opening of supply region As is provided above track unit 40. When track unit 40 is attached to feeder main body 31, opening and closing operations of shutter 48 are controlled by a shutter drive device (not illustrated). By opening and closing shutter 48, bulk feeder 30 can prevent a component from protruding and a foreign matter from being introduced into supply region As.

### 4. Configuration of Mounting Assistance Device 50

A configuration of mounting assistance device 50 will be described with reference to FIGS. 4 to 13. Mounting assistance device 50 assists recognition processing of a supply state of a component performed by control device 20 of component mounter 10 in a mounting process. The recognition processing of the supply state includes image processing, and the image processing includes a determination of whether a component supplied to supply region As of bulk feeder 30 is appropriate for a target of a collection operation by component mounter 10.

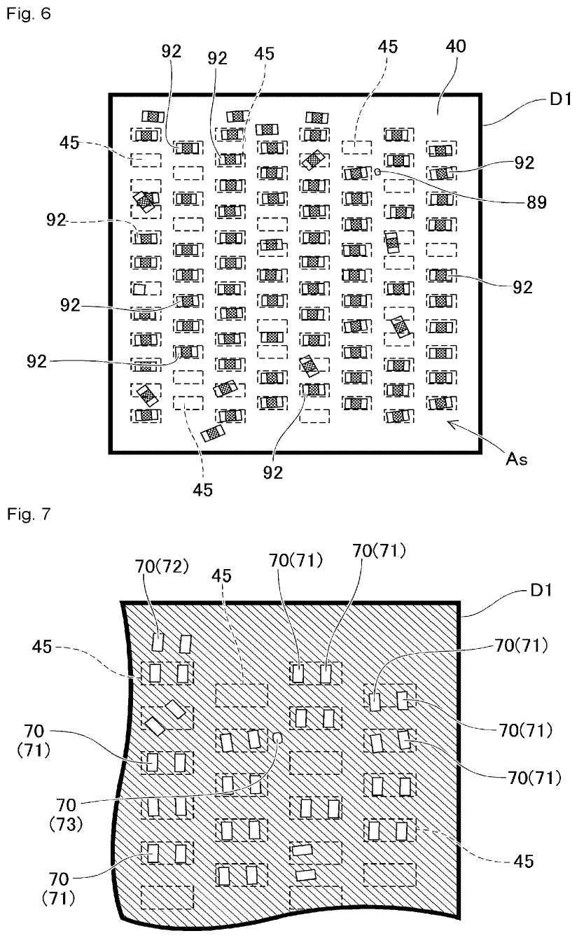

Specifically, control device 20 performs image processing on image data D1 (see FIG. 6) acquired by capturing an image with a camera (board camera 15 in the present embodiment), recognizes whether there is a component appropriate for a target of a collection operation in supply region As, and recognizes a position and an angle of the component when there is a component appropriate for the collection operation. Then, control device 20 controls an operation of mounting head 133 in a collection operation based on a result of recognition processing of a supply state.

In the above-described appropriateness determination, when there is an erroneous determination in the image processing such as erroneously recognizing some of multiple components as one component or erroneously recognizing a foreign matter as a part of a component, a position and a posture of a recognized component (hereinafter, also referred to as a “recognition component”) are different from an actual position and an actual posture, which can cause a mistake in the collection operation. In addition, even when a component can be collected, there is a possibility that processing to be performed thereafter, for example, a component transfer operation or a component mounting operation is affected.

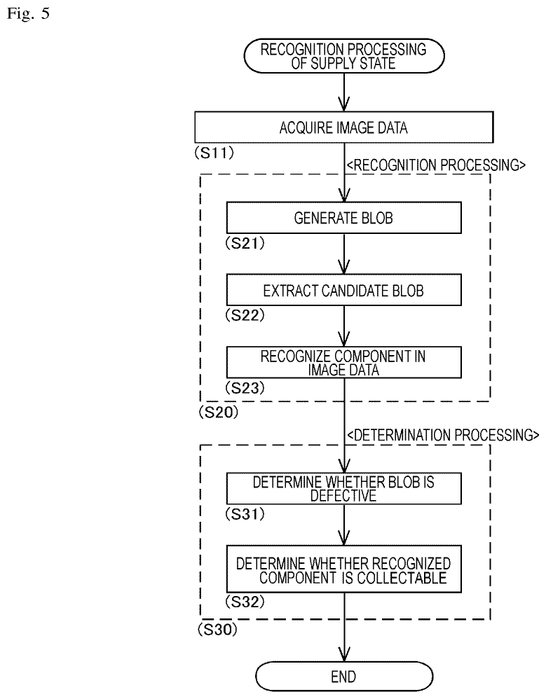

Therefore, in the present embodiment, mounting assistance device 50 incorporated in control device 20 of component mounter 10 adopts a configuration capable of improving accuracy of image processing included in recognition processing (see FIG. 5) in a supply state of a component. Specifically, as illustrated in FIG. 4, mounting assistance device 50 includes recognition section 51 and determination section 52. As illustrated in FIG. 5, mounting assistance device 50 acquires image data D1 acquired by capturing an image with board camera 15 (S11). Recognition section 51 performs recognition processing S20 by using image data D1. Determination section 52 performs determination processing S30 for determining whether a component is appropriate for a collection operation.

### 5-2. Recognition Section 51

Recognition section 51 performs image processing on image data D1 acquired by capturing the image of supply region As in which multiple cavities 45 for individually accommodating multiple components 92 are formed, and acquires information on recognition component 80. In the present embodiment, blob analysis is adopted as a method of recognizing components 92 scattered in supply region As as recognition components 80.

Specifically, recognition section 51 first performs generation step S21 of generating multiple blobs 70 for image data D1. Specifically, recognition section 51 binarizes image data D1 by using a predetermined threshold, and sets, for example, white when a luminance value of each pixel is higher than the threshold, and sets black, for example, when the luminance value is lower than or equal to the threshold. FIG. 7 illustrates a part of binarized image data D1 in an enlarged manner, and cavities 45 before processing are indicated by dashed lines. Blobs 70 correspond to white closed regions in binarized image data D1.

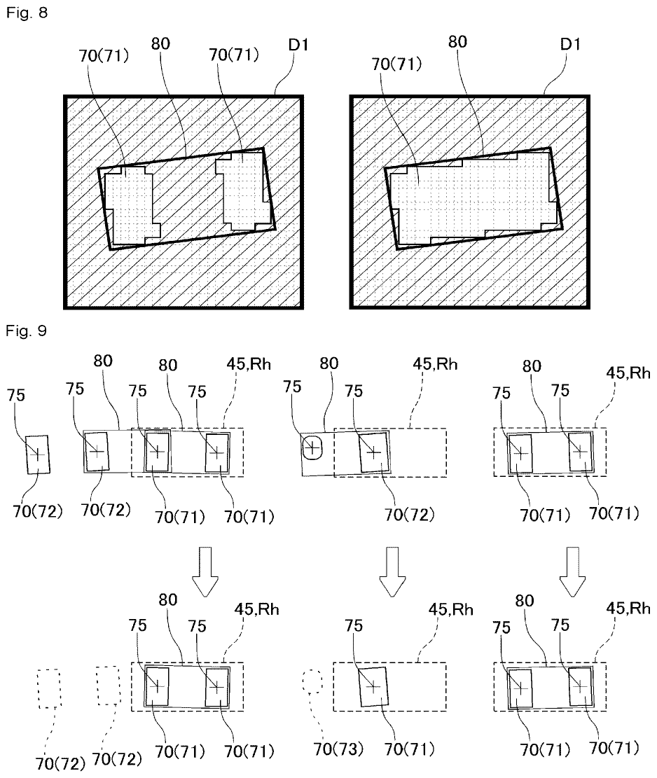

Here, it is assumed a case where blob 70 indicates, for example, a pair of electrode portions formed at both ends in a longitudinal direction of component 92 as illustrated on the left side of FIG. 8, and indicates entirety including a body of component 92 as illustrated on the right side of FIG. 8. These are different from each other depending on the type of component 92 (including color and gloss of the body and the electrode) and a threshold used for binarization. In the present embodiment, in recognition processing S20, component 92 is recognized by one or two blobs 70.

However, as illustrated in FIG. 9, blob 70 in binarized image data D1 can include, for example, component 92 that is not accommodated in cavity 45 or foreign matter 89 (see FIG. 6). When these defective blobs 72 and 73 are erroneously recognized as a part of component 92, accuracy of the recognition processing decreases. Therefore, recognition section 51 extracts candidate blob 71 appropriate for recognition processing from among multiple blobs 70 (S22). In other words, this extraction step is a process of removing blobs 70 (72 and 73) inappropriate for recognition processing.

Specifically, recognition section 51 extracts candidate blob 71 from among multiple blobs 70, each of whose central positions 75 is included in appropriate region Rh defined based on positions of multiple cavities 45 (S22). Specifically, recognition section 51 first acquires central position 75 for each of multiple blobs 70. Central position 75 may be the center of a circumscribed rectangle of blob 70 or the center of gravity of the circumscribed rectangle.

In addition, “appropriate region Rh” defined based on a position of cavity 45 is a region obtained by adding an allowable error to a region in which the center of blob 70 corresponding to component 92 can be present with respect to cavity 45 when component 92 is accommodated in cavity 45, and is set to, for example, a region having the same shape as cavity 45. Recognition section 51 extracts blob 70 of which central position is included in appropriate region Rh set based on cavity information M3 as candidate blob 71 (illustrated in a lower portion of FIG. 9).

Accordingly, for example, defective blob 72 corresponding to a closed region of component 92 not accommodated in cavity 45 or defective blob 73 corresponding to foreign matter 89 located outside cavity 45 can be removed so as not to be used in subsequent processing. In extraction step S22, depending on a relationship with the subsequent processing, extraction using central position 75 of blob 70 and appropriate region Rh as described above can be omitted, and an aspect in which candidate blob 71 corresponding to a closed region of at least a part of component 92 among multiple blobs 70 is extracted (partial inclusion of a defective blob is permitted) may be simply adopted.

Subsequently, recognition section 51 performs recognition step S23 of recognizing a rectangular region including one or more candidate blobs 71 as component 92 in image data D1. In the present embodiment, as illustrated in FIG. 8, recognition section 51 recognizes a rectangular region circumscribing one or more candidate blobs 71 as component 92 in image data D1. Accordingly, for example, recognition component 80 configured with pair of candidate blobs 71 and recognition component 80 configured with one candidate blob 71 are acquired.

Recognition section 51 also recognizes information necessary for subsequent processing such as reference position Ps, an angle (supply angle Ls), a shape (including lengths of a short side and a long side), and an area (corresponding to the number of pixels included in a rectangular region) in supply region As for each of multiple recognition components 80. By such processing, recognition section 51 recognizes a supply state of component 92 in supply region As and stores a recognition result in storage section 21.

In recognition processing S20 described above, it is assumed that component mounter 10 targets only component 92 appropriately accommodated in cavity 45 as a target of a collection operation. Thus, when bulk feeder 30 is a type that does not have cavity 45 in supply region As, recognition section 51 may extract candidate blob 71 from among multiple blobs 70 under a condition that, for example, candidate blob 71 has an area of a certain range and a blob shape close to a rectangular shape, and may acquire a position and a shape of recognition component 80 in supply region As.

### 5-3. Determination Section 52

Determination section 52 determines whether component 92 (recognition component 80) recognized in recognition processing S20 is appropriate for a target of a collection operation by component mounter 10 based on a supply state of component 92 (S30). Here, in recognition processing S20, even when recognition component 80 is recognized by using candidate blob 71 corresponding to a closed region of at least a part of component 92, there is a case where recognition component 80 is not appropriate for the collection operation.

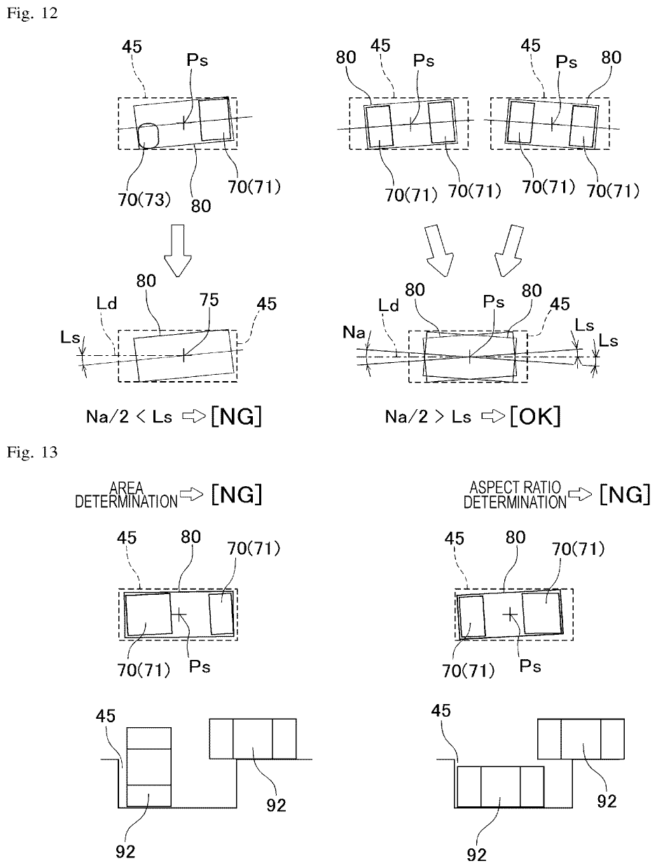

As a cause thereof, for example, when two components 92 are accommodated in cavity 45 such that longitudinal directions thereof are vertical direction (see the left side of FIG. 11), it is assumed that an electrode portion of each component 92 is erroneously recognized as an electrode portion of one component 92 and recognition component 80 is recognized. In addition, when at least a part of another component 92 overlaps component 92 accommodated in cavity 45 (see the right side of FIG. 13), it is assumed the component is erroneously recognized in the same manner as described above.

In addition, when removal processing of blob 70 outside cavity 45 is omitted in recognition processing S20, it is assumed that defective blob 73 corresponding to foreign matter 89 is erroneously recognized as a part of component 92 and recognition component 80 is recognized. In addition, even when the above-described removal processing is performed, for example, when each of electrode portions of two components 92 is located inside cavity 45 in a top view, it is assumed that component 92 having the electrode portion is erroneously recognized as being present and recognition component 80 is recognized.

In the present embodiment, a cause of the erroneous recognition assumed as described above is added, and various aspects are adopted for appropriateness determination. Aspects (S31 and S32) of appropriateness determination to be described below can be appropriately combined or partially omitted in consideration of the type of component 92, an imaging environment, a form of supply region As of bulk feeder 30, and the like.

Determination section 52 first determines whether blobs 70 are defective based on the number of blobs 70 (candidate blobs 71) configuring recognition component 80 (S31). Specifically, determination section 52 determines whether an area of blob 70 falls within a certain range set in advance according to the number of blobs 70 configuring recognition component 80. When an area of at least one of blobs 70 configuring recognition component 80 is not within a certain range, for example, determination section 52 determines that blob 70 is a foreign matter in cavity 45 or component 92 in an inappropriate posture, and blob 70 is defective.

In addition to or instead of the determination based on an area, determination section 52 determines whether blob 70 is defective by determining whether a shape of blob 70 configuring recognition component 80 is similar to a shape corresponding to a closed region of component 92. That is, whether blob 70 is defective is determined based on whether blob 70 is similar to the entire shape of component 92 when blob 70 is one, and based on whether blob 70 is similar to each of shapes of a pair of electrode portions of component 92 when blob 70 is two.

Next, determination section 52 determines whether recognition component 80 is component 92 supplied to be collectable in supply region As (S32). Specifically, determination section 52 selectively performs following determinations (A) to (E). In the present embodiment, determination section 52 performs all determinations (A) to (E) in series.

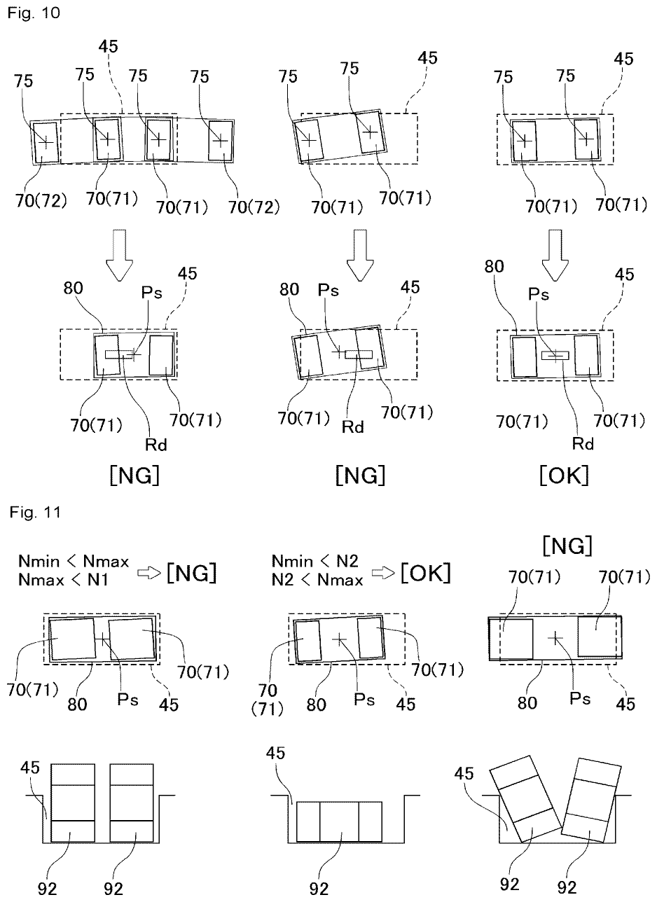

In determination (A), determination section 52 determines whether recognition component 80 can be collected based on whether reference position Ps of recognized component 92 (recognition component 80) is present in defined region Rd. In the present embodiment, reference position Ps of component 92 (recognition component 80) is set at a central position of component 92 as illustrated in FIG. 10.

In addition, above-described “defined region Rd” is a region defined based on a shape of cavity 45 that accommodates component 92, and in the present embodiment, is set to region Rc in which the center of component 92 can be located when component 92 is appropriately accommodated in cavity 45. When reference position Ps of recognition component 80 is not in defined region Rd, determination section 52 determines that component 92 is not appropriately accommodated in cavity 45 and is not appropriate for a target of a collection operation (FIG. 10: NG).

In determination (B), determination section 52 determines whether recognition component 80 can be collected based on a histogram related to pixels of recognition component 80 in image data D1. Specifically, a histogram of luminance values of multiple pixels located inside a rectangular shape of recognition component 80 is generated, and when a shape of the histogram is not similar to a histogram generated for normal component 92, determination section 52 determines that recognition component 80 is not appropriate for a collection operation.

Specifically, as illustrated in FIG. 11, determination section 52 may determine whether collection is possible based on whether the numbers of pixels N1 and N2 of a predetermined luminance value (for example, 255 indicating white) in a histogram are within a normal range (Nmin to Nmax). For example, when two components 92 are accommodated in cavity 45 such that a longitudinal direction thereof is a vertical direction, even when recognition component 80 has a normal outer shape, an image of an electrode portion is captured to be greater than usual, and the number of pixel N2 having a white luminance value exceeds a normal range (N2>Nmax). In such a case, determination section 52 determines that recognition component 80 is not appropriate for a target of a collection operation (FIG. 11: NG).

In determination (C), determination section 52 determines whether recognition component 80 can be collected based on defined angle Ld in supply region As and supply angle Ls of recognized component 92 (recognition component 80). Above-described defined angle Ld is an angle defined based on a shape of cavity 45 that accommodates component 92, and in the present embodiment, as illustrated in FIG. 12, is an angle with a longitudinal direction of cavity 45 (the left-right direction in FIG. 12) as 0 degrees.

Supply angle Ls of recognition component 80 is an angle acquired in recognition processing S20, and is an angle formed by a longitudinal direction of a rectangular region circumscribing candidate blob 71 with respect to a reference direction (Y direction in the present embodiment) of supply region As. Determination section 52 determines whether component 92 is appropriate for a target of a collection operation based on whether supply angle Ls of component 92 is within range Na that can be taken with respect to defined angle Ld when component 92 is appropriately accommodated in cavity 45. Above-described range Na is set in advance based on a shape of cavity 45 and a shape of component 92.

For example, another component 92 can be placed above component 92 normally accommodated in cavity 45. In this regard, according to above-described determination (C), when supply angle Ls of another component 92 is not in range Na that can be taken with respect to defined angle Ld, determination section 52 can determine that another component 92 is not appropriate for a target of a collection operation (FIG. 12: NG).

In determination (D), based on a shape or an area of recognized component 92 (recognition component 80), determination section 52 determines whether component 92 is appropriate for a target of a collection operation by component mounter 10. Here, for example, as illustrated on the left side of FIG. 13, when one component 92 is accommodated in cavity 45 in an erected state and another component 92 is located outside cavity 45, recognition component 80 can be recognized by using candidate blob 71 located inside cavity 45.

In addition, for example, as illustrated on the right side of FIG. 13, when at least a part of another component 92 overlaps component 92 accommodated in cavity 45, recognition component 80 can be recognized by using candidate blob 71 located inside cavity 45. However, such recognition component 80 can be different in an area or a shape from normal recognition component 80.

Therefore, as an aspect of the appropriateness determination based on an area, when an area of component 92 (recognition component 80) calculated based on the numbers of pixels included in a rectangular region in image data D1 is out of a defined range, determination section 52 determines that corresponding component 92 is not appropriate for a target of a collection operation by component mounter 10 (FIG. 13: NG). The above-described “defined range” is set to a range obtained by adding an allowable error based on an individual difference in manufacturing, an imaging condition, and image processing to an apparent area occupied in image data D1 when normal component 92 is an imaging target. When an area based on the number of pixels of recognition component 80 falls within the defined range, it is determined to be appropriate in determination (D).

In addition, when a ratio (aspect ratio) between a short side and a long side of recognized component 92 (recognition component 80) is out of a defined range as an aspect of appropriateness determination based on a shape, determination section 52 determines that component 92 (recognition component 80) is not appropriate for a target of a collection operation by component mounter 10 (FIG. 13: NG). The above-described “defined range” is set to a range obtained by adding an allowable error based on an individual difference in manufacturing, an imaging condition, and image processing to a ratio between a short side and a long side of normal component 92. When the aspect ratio of recognition component 80 falls within the defined range, it is determined to be appropriate in determination (D).

In determination (E), determination section 52 determines whether recognition component 80 is appropriate for a target of a collection operation based on an accommodation degree of recognition component 80 in image data D1 and cavity 45. Here, for example, as illustrated in the right side of FIG. 11, when two components 92 are accommodated in cavity 45 such that longitudinal directions thereof are inclined in a vertical direction, even when recognition component 80 has a normal outer shape, a part of the outer shape may protrude from cavity 45. Therefore, determination section 52 first recognizes cavity 45 closest to component 92 (recognition component 80) in image data D1. At this time, determination section 52 can recognize cavity 45 estimated to accommodate recognition component 80 based on image data D1 and cavity information M3.

Next, determination section 52 determines whether entirety of recognition component 80 is accommodated in cavity 45. When a part of recognition component 80 is not accommodated in cavity 45 (the right side in FIG. 11), determination section 52 determines that component 92 (recognition component 80) is not appropriate for a target of a collection operation by component mounter 10 (FIG. 11: NG). Meanwhile, when entirety of recognition component 80 is accommodated in cavity 45 (the center of FIG. 11), it is determined to be appropriate in determination (E) (FIG. 11: OK). In determination of whether entirety of recognition component 80 is accommodated, an allowable error of image processing or the like may be added.

Determination processing S30 including quality determination of blob (S31) and appropriateness determination of recognition component 80 (S32) described above is subsequently performed for all of recognition components 80 recognized by recognition section 51. Accordingly, mounting assistance device 50 acquires a determination result of whether each of multiple recognition components 80 is appropriate for a collection operation. The determination result is stored as, for example, information indicating whether component 92 that can be collected is accommodated in each of multiple cavities 45. In addition, information, such as reference position Ps (central position) and supply angle Ls, is associated with collectable component 92.

### 6. Mounting Process by Component Mounter 10

A mounting process by component mounter 10 will be described. Here, it is assumed that bulk feeder 30 is equipped in component supply device 12. After bulk feeder 30 is set in slot 121, control device 20 performs calibration processing and recognizes positions of multiple cavities 45 within the mounter. In the above-described calibration processing, control device 20 first moves board camera 15 above reference mark 49 of bulk feeder 30 and acquires image data by capturing an image with board camera 15.

Then, control device 20 recognizes a position of bulk feeder 30 within the mounter based on positions of pair of reference marks 49 included in the image data by image processing and a position of board camera 15 when capturing an image. Control device 20 can acquire a coordinate value of each cavity 45 based on a result of calibration processing and cavity information M3 indicating an arrangement of cavities 45.

In the mounting process, first, board conveyance device 11 of component mounter 10 performs a loading process of board 91. Accordingly, board 91 is loaded into the mounter and positioned at a predetermined position within the mounter. Control device 20 causes bulk feeder 30 to perform a supply operation after or in parallel with the loading process of board 91. By performing the supply operation, multiple components 92 are accommodated in at least some of multiple cavities 45 of bulk feeder 30. After the supply operation by bulk feeder 30 is completed, mounting assistance device 50 performs recognition processing of a supply state of component 92.

Accordingly, specific information (such as an address of cavity 45) of cavity 45 that accommodates current component 92 in a collectable manner as the supply state, and reference position Ps and supply angle Ls of collectable component 92 (component 92 appropriate for a collection operation) are acquired. Next, control device 20 performs the PP cycle. In the PP cycle, control device 20 performs a collection cycle in which a collection operation for collecting components 92 is repeated by using multiple suction nozzles 134. At this time, control device 20 controls an operation of mounting head 133 in a collection operation such that mounting head 133 is subsequently positioned according to reference position Ps of collectable component 92. At this time, control device 20 determines an angle of suction nozzle 134 according to supply angle Ls of collectable component 92.

Subsequently, control device 20 performs recognition processing of a holding state of components 92 respectively held by multiple suction nozzles 134. Specifically, control device 20 moves mounting head 133 over part camera 14 and sends an imaging command to part camera 14. Control device 20 performs image processing on the image data acquired by capturing an image with part camera 14 and recognizes a posture (position and angle) of component 92 held by each of multiple suction nozzles 134. A result of the recognition processing of the holding state is recorded in storage section 21 as an operation result indicating whether collection mistake occurs in the collection operation.

Thereafter, control device 20 performs a mounting cycle in which a mounting operation for mounting components is repeated by using multiple suction nozzles 134. In the mounting operation of the mounting cycle, control device 20 controls an operation of mounting head 133 such that each of components 92 is mounted at a mounting position designated by control program M1. Further, control device 20 controls the operation of mounting head 133 such that suction nozzle 134 is positioned and angled with respect to the mounting position based on a result of the recognition processing.

In addition, control device 20 performs supply management processing of component 92 in parallel with the PP cycle described above. The supply management processing includes setting of execution timing of a supply operation of component 92 by bulk feeder 30, a command of the supply operation, recognition processing of a supply state, and the like. For example, when a supply operation of component 92 is performed, the supply operation by bulk feeder 30 is performed in a period from the completion of a collection cycle of a current PP cycle to the start of a collection cycle of the next PP cycle. When the supply operation by bulk feeder 30 is performed, mounting assistance device 50 performs again the recognition processing of the above-described supply state.

Control device 20 performs an unloading process of board 91 when all the PP cycles are completed based on control program M1. In the unloading process of board 91, board conveyance device 11 unclamps positioned board 91 and unloads board 91 outside component mounter 10.

### 7. Effect of Configuration of Embodiment

According to a configuration of mounting assistance device 50 described above, it is possible to improve accuracy of image processing in recognition processing of a supply state of component 92 supplied by bulk feeder 30. Accordingly, it is possible to prevent a mistake from occurring in a collection operation by component mounter 10, and as a result, it is possible to maintain high productivity in component mounter 10.

### 8. Modification Aspect of Embodiment

In the embodiment, mounting assistance device 50 is configured to be incorporated in control device 20 of component mounter 10. Alternatively, a part or all of mounting assistance device 50 may be incorporated in host computer 60 and other external devices. For example, mounting assistance device 50 may be a dedicated device that is incorporated in host computer 60 or installed in production line Ln.

### Reference Signs List

10: component mounter, 12: component supply device, 13: component transfer device, 131: head driving device, 132: movement table, 133: mounting head, 134: suction nozzle, 14: part camera, 15: board camera, 20: control device, 21: storage section, 30: bulk feeder, 31: feeder main body, 40: track unit, 45: cavity, 46: side wall, 47: front end portion, 48: shutter, 49: reference mark, 50: mounting assistance device, 51: recognition section, 52: determination section, 60: host computer, 70: blob, 71: candidate blob, 72,73: defective blob, 75: central position (of blob), 80: recognition component, 89: foreign matter, 91: board, 92: component, As: supply region, R: conveyance path, M1: control program, M2: component data, M3: cavity information, D1: image data, Rd: defined region, Rc: region (in which component center can be located in cavity), Ls: supply angle, Ld: defined angle, Na: range (in which supply angle can be taken at defined angle in cavity), Ps: reference position

1. A mounting assistance device comprising:
a recognition section configured to perform image processing on image data acquired by capturing an image of a supply region in which multiple components are supplied in a bulk state, and recognize the component in the supply region, the image processing including a generation step of generating multiple blobs, an extraction step of extracting a candidate blob corresponding to a closed region of at least a part of the component from among the multiple blobs, and a recognition step of recognizing a rectangular region including one or more of the candidate blobs as the component in the image data, and
a determination section configured to determine whether the component is appropriate for a target of a collection operation by a component mounter based on a shape or an area of the recognized component.

2. The mounting assistance device according to claim 1, wherein the recognition section recognizes the rectangular region circumscribing one or more of the candidate blobs as the component in the image data in the recognition step.

3. The mounting assistance device according to claim 1, wherein when a ratio between a short side and a long side of the recognized component is out of a defined range, the determination section determines that the component is not appropriate for the target of the collection operation by the component mounter.

4. The mounting assistance device according to claim 1, wherein when an area of the recognized component is out of a defined range, the determination section determines that the component is not appropriate for the target of the collection operation by the component mounter.

5. The mounting assistance device according to claim 1, wherein
multiple cavities individually accommodating the multiple components are formed in the supply region,
the recognition section performs the image processing on the image data and recognizes a position and the shape of the component in the supply region, and
the determination section determines whether the component is appropriate for the target of the collection operation by the component mounter based on whether entirety of the recognized component is accommodated in the cavity closest to the component in the image data.

6. A mounting assistance device comprising:
a recognition section configured to perform image processing on image data acquired by capturing an image of a supply region in which multiple cavities individually accommodating multiple components are formed and recognize a position and a shape of the component in the supply region; and
a determination section configured to determine whether the component is appropriate for a target of a collection operation by a component mounter based on whether entirety of the recognized component is accommodated in the cavity closest to the component in the image data.
